(19) United States
(12) Patent Application Publication
(10) Pub. No.: US 2024/0200574 A1
(43) Pub. Date: Jun. 20, 2024

(54) MOUNTING ASSEMBLY FOR ELECTRICAL FAN, ASSOCIATED CABINET AND MOUNTING METHOD

(71) Applicant: ABB Schweiz AG, Baden (CH)

(72) Inventor: Fawei Zhang, Shanghai (CN)

(21) Appl. No.: 18/556,947

(22) PCT Filed: Jul. 8, 2021
(86) PCT No.: PCT/CN2021/105333

§ 371 Date: Oct. 24, 2023

(51) Int. Cl. F04D 29/60; F04D 25/06; H05K 7/20

(52) U.S. Cl. CPC F04D 29/601; F04D 25/06; H05K 7/20172

(57) ABSTRACT

A mounting assembly for an electrical fan, an associated cabinet, and a mounting method. The mounting assembly includes a limiting member arranged on a side wall of a cabinet so that a cavity is formed between the side wall and the limiting member for receiving the electrical fan. The limiting member is configured to define the cavity with an opening through which the electrical fan is inserted into the cavity along an insertion direction. A stopping member is arranged on a cover of the cabinet and adapted to press the electrical fan in the insertion direction when the cover is mounted on the side wall.

### FIELD

Embodiments of the present disclosure generally relate to an electric machine, and more specifically, to an air duct assembly for a rotor of an electric machine.

### BACKGROUND

A control cabinet such as for an industrial computer or a control system is typically used to receive electronic devices and provide protection for the electronic devices. Since electronic devices generate a lot of heat during operation, at least one electrical fan is usually provided in the cabinet to dissipate heat.

Nowadays, most of the electronic devices can be mounted in a cabinet automatically with automatic means, for example, by a robot. The automatic mounting of the electronic devices in the cabinet can significantly improve the mounting efficiency of the industrial computer or the control system. In addition, in comparison with manual mounting, because automated mounting is less error-prone and eliminates the influence of static electricity, etc., the stability of the industrial computer assembled automatically is higher. However, due to the need for multiple fasteners and positioning, the installation of the electrical fan in the cabinet usually needs to be done manually, which reduces the assembly efficiency.

### SUMMARY

Embodiments of the present disclosure provide a mounting assembly for an electrical fan, an associated cabinet and a mounting method.

In a first aspect, a mounting assembly for an electrical fan is provided. The mounting assembly comprises a limiting member arranged on a side wall of a cabinet so that a cavity is formed between the side wall and the limiting member for receiving the electrical fan, the cavity comprising an opening through which the electrical fan is inserted into the cavity along an insertion direction; and a stopping member arranged on a cover of the cabinet and adapted to press the electrical fan in the insertion direction when the cover is mounted on the side wall.

With the mounting assembly according to embodiments of the present disclosure, the limiting member can limit the electrical fan within the cavity formed by the limiting member and the side wall and the stopping member can prevent the electrical fan from escaping from the cavity. As a result, the electrical fan can be mounted on the side wall without using fasteners. In this way, the electrical fan is allowed to be mounted on the side wall of the cabinet with automated means, such as robots, etc., to thereby improve the assembly efficiency of the cabinet.

In some embodiments, the mounting assembly further comprises a first cushion arranged between the limiting member and the side wall to provide cushion for the electrical fan. In this way, the noise cause by vibration of the electrical fan during operation can be significantly reduced, thereby improving the user experience.

In some embodiments, the mounting assembly further comprises a second cushion arranged between the stopping member and the electrical fan. In this way, the noise cause by vibration of the electrical fan during operation can be significantly reduced, thereby improving the user experience.

In some embodiments, the limiting member comprises a pair of half portions arranged at opposite sides of the electrical fan, each of the half portions comprising a first bent portion bent away from the electrical fan and adapted to be attached on the side wall; and a second bent portion bent towards the electrical fan and adapted to limit the electrical fan together with the side wall without blocking airflow provided by the electrical fan. With the arrangement, the limiting member can be manufactured more easily. Furthermore, the distance between the pair of half portions can be adjusted to adapt to a variety of electrical fans with different sizes.

In some embodiments, the half portion further comprises an intermediate portion arranged between the first and second bent portions and adapted to limit the electrical fan between the intermediate portions.

In some embodiments, the first cushion comprises a first portion arranged between the second bent portion and the electrical fan; and a second portion arranged between the intermediate portion and the electrical fan. The cushion can provide cushion for the electrical fan in various directions.

In some embodiments, the first cushion further comprises a fourth portion arranged on a bottom wall of the cabinet opposite to the cover. In this way, the noise cause by vibration of the electrical fan during operation can be further reduced, thereby improving the user experience.

In some embodiments, the limiting member is integrally formed and comprises a pair of first bent portions bent away from the electrical fan and adapted to be attached on the side wall; a limiting portion adapted to limit the electrical fan together with the side wall, the limiting portion comprising at least one vents for airflow provided by the electrical fan to pass through; and a pair of intermediate portions arranged between the limiting portion and the pair of first bent portions and adapted to limit the electrical fan therebetween. In this way, the limiting member can be mounted on the side wall more easily.

In a second aspect, a cabinet is provided. The cabinet comprises side walls and a bottom wall forming an internal space for receiving electrical devices; a cover for covering the internal space; and at least one mounting assembly according to the first aspect of the present disclosure for mounting at least one electrical fan on at least one of the side walls.

In some embodiments, the cabinet further comprises a fixed part arranged in the internal space and adapted for a socket to be arranged thereon, the socket adapted to receive a plug of the electrical fan to provide electrical connections for the electrical fan. This arrangement can further facilitate the automatic mounting of the electrical fan.

In a third aspect, a method of mounting an electrical fan in a cabinet with an automated mean is provided. The method comprises gripping the electrical fan; moving and inserting the electrical fan into a cavity formed between a side wall of the cabinet and a limiting member of a mounting assembly; inserting a plug of the electrical fan into a socket arranged on a fixed part arranged in an internal space of the cabinet; and gripping and moving a cover for the cabinet to cover the internal space to make a first cushion press the electrical fan.

It is to be understood that the Summary is not intended to identify key or essential features of embodiments of the present disclosure, nor is it intended to be used to limit the scope of the present disclosure. Other features of the present disclosure will become easily comprehensible through the description below.

### BRIEF DESCRIPTION OF THE DRAWINGS

The above and other objectives, features and advantages of the present disclosure will become more apparent through more detailed depiction of example embodiments of the present disclosure in conjunction with the accompanying drawings, wherein in the example embodiments of the present disclosure, same reference numerals usually represent the same components.

FIGS. 1 and 2 show perspective views of a cabinet according to embodiments of the present disclosure;

FIG. 3 shows a top view of a cabinet without a cover according to embodiments of the present disclosure;

FIG. 4 shows a view of section B-B of a cabinet as shown in FIG. 3;

FIG. 5 shows a perspective view of a half portion of a limiting member according to embodiments of the present disclosure;

FIG. 6 shows a top view of a half portion of a limiting member according to embodiments of the present disclosure;

FIG. 7 shows a side view of a half portion of a limiting member according to embodiments of the present disclosure;

FIG. 8 shows a side view of an integrally formed limiting member according to embodiments of the present disclosure;

FIG. 9 shows a top view of an integrally formed limiting member according to embodiments of the present disclosure; and

FIG. 10 shows a flowchart illustrating a method of mounting an electrical fan in a cabinet with an automated mean according to embodiments of the present disclosure.

Throughout the drawings, the same or similar reference symbols are used to indicate the same or similar elements.

### DETAILED DESCRIPTION

The present disclosure will now be discussed with reference to several example embodiments. It is to be understood these embodiments are discussed only for the purpose of enabling those skilled persons in the art to better understand and thus implement the present disclosure, rather than suggesting any limitations on the scope of the subject matter.

As used herein, the term “comprises” and its variants are to be read as open terms that mean “comprises, but is not limited to.” The term “based on” is to be read as “based at least in part on.” The term “one embodiment” and “an embodiment” are to be read as “at least one embodiment.” The term “another embodiment” is to be read as “at least one other embodiment.” The terms “first,” “second,” and the like may refer to different or same objects. Other definitions, explicit and implicit, may be comprised below. A definition of a term is consistent throughout the description unless the context clearly indicates otherwise.

A control cabinet is used to house electronic devices used to realize various functions and provide them with protection. At present, the assembly of the control cabinet and its internal electronic devices is usually completed by automatic means such as robots, which has high assembly efficiency and consistency. However, the electrical fan used for heat dissipation in the control cabinet requires multiple fasteners and positioning to complete the installation. Therefore, the electrical fan is usually installed manually. This reduces the assembly efficiency and assembly reliability of the control cabinet.

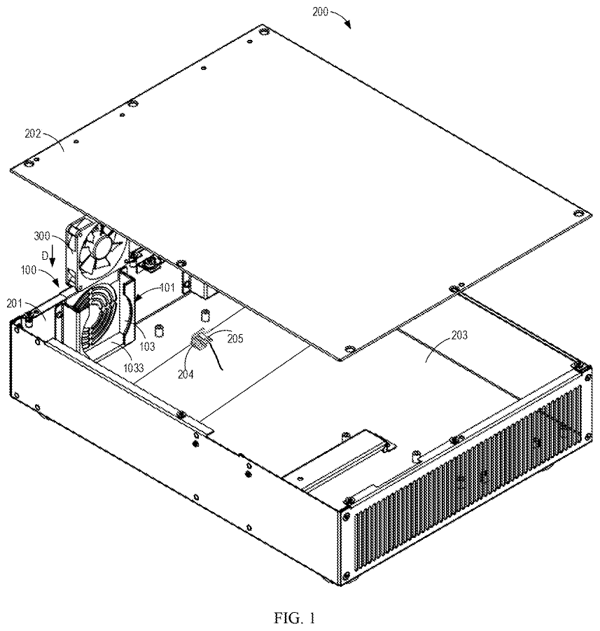

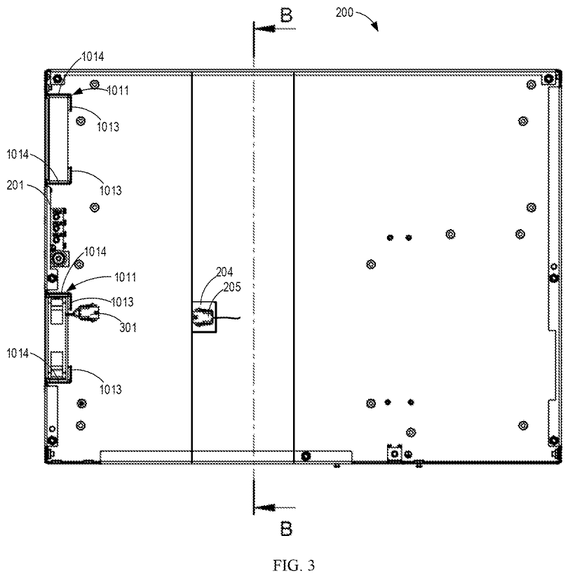

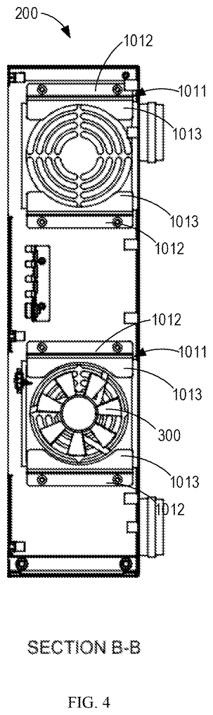

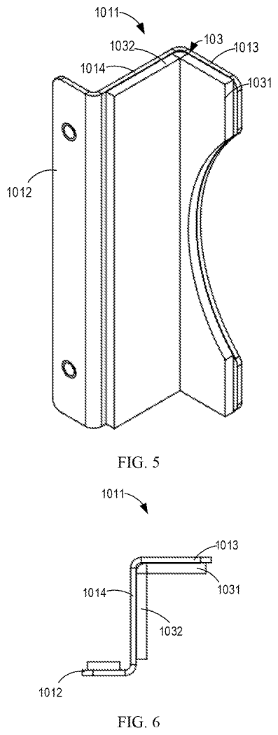

In order to at least partially address the above and other potential problems and at least to improve the assembly efficiency of the cabinet 200, embodiments of the present disclosure provide a mounting assembly 100 allowing automated mounting of an electrical fan 300 in the cabinet 200. Now some example embodiments will be described with reference to FIGS. 1-9.

FIGS. 1-3 show the cabinet 200 where the electrical fan 300 needs to be installed. It is to be understood that the cabinet 200 as described herein may not only refer to the cabinet 200 of an industrial computer or an industrial control system, but also any suitable cabinet 200 or housing, for example, of a personal computer, etc., with at least one electrical fan 300 that needs to be installed to improve the heat dissipation. Embodiments of the present disclosure will be discussed by taking the cabinet as shown in FIGS. 1-3 as an example of the cabinet 200. It is to be understood that any other suitable cabinet 200 is similar, and will not repeated respectively in the following.

As shown in FIGS. 1-3, the cabinet 200 comprises four side walls 201 and a bottom wall 203 which together form an internal space for receiving electronic devices. There are vents provided on at least one of side walls 201 and/or bottom wall 203 to facilitate airflow for heat dissipation. The bottom wall 203 may be installed on the side walls 201 by fasteners or welding or the like. To cover the internal space, the cabinet 200 further comprises a cover 202. The cover 202 may be mounted on the side walls 201 by fasteners or snap connection.

At least one mounting assembly 100 according to embodiments of the present disclosure may be provided on at least one of side walls 201 for mounting at least one electrical fan 300. Now some example embodiments will be described with reference to FIGS. 1-9 to describe example structures of the mounting assembly 100.

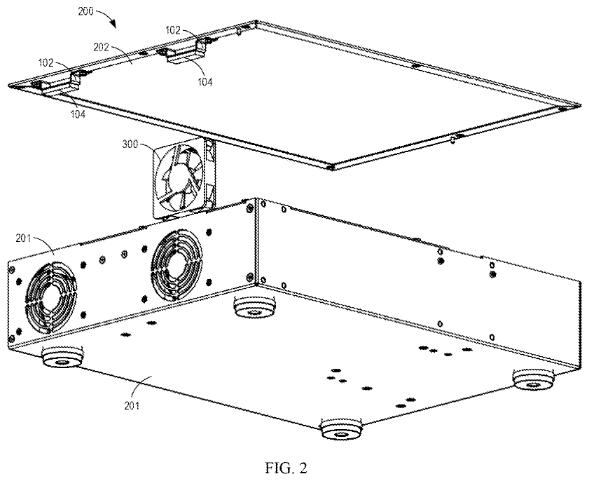

As shown in FIGS. 1 and 2, the mounting assembly 100 generally comprises a limiting member 101 and a stopping member 102. The limiting member 101 is arranged on a side wall 201 of the cabinet 200 so that a cavity for receiving the electrical fan 200 is formed between the limiting member 101 and the side wall 201. The cavity comprises an opening through which the electrical fan 300 can be inserted into the cavity in an insertion direction D.

The stopping member 102 is arranged on the cover 202 of the cabinet 200. When the cover 202 is mounted on the side walls 201 of the cabinet 200, the stopping member 102 can press the electrical fan 300 in the insertion direction D to thereby secure the electrical in the cavity.

That is, the limiting member 101 can limit the electrical fan 300 within the cavity formed between the limiting member 101 and the side wall 201 and the stopping member 102 can prevent the electrical fan 300 from escaping from the cavity. As a result, the electrical fan 300 can be mounted on the side wall 201 without using fasteners. In this way, the electrical fan 300 is allowed to be mounted on the side wall 201 of the cabinet 200 with automated means, such as robots, etc., to thereby improve the assembly efficiency of the cabinet 200.

The limiting member 101 may have any suitable structure to provide a cavity with the side wall 201. For example, in some embodiments, the limiting member 101 may comprise a pair of half portions 1011 respectively arranged at opposite sides of the electrical fan 300. FIGS. 5-7 show an example structure of one of the pair of half portions 1011 of the limiting member 101. As shown in FIGS. 5-7, the half portion 1011 comprises two bent portions, namely, a first bent portion 1012 and a second bent portion 1013.

The first bent portion 1012 is bent away from the electrical fan 300 and used to be attached on the side wall 201. In this way, the half portion 1011 can be mounted on the side wall 201. The first bent portion 1012 may be attached on the side wall 201 in any suitable means. For example, in some embodiments, the first bent portion 1012 may be detachably attached on the side wall 201 with fasteners. In this way, the half portion 1011 can be replaced, for example, when an electrical fan 300 with different size needs to be mounted.

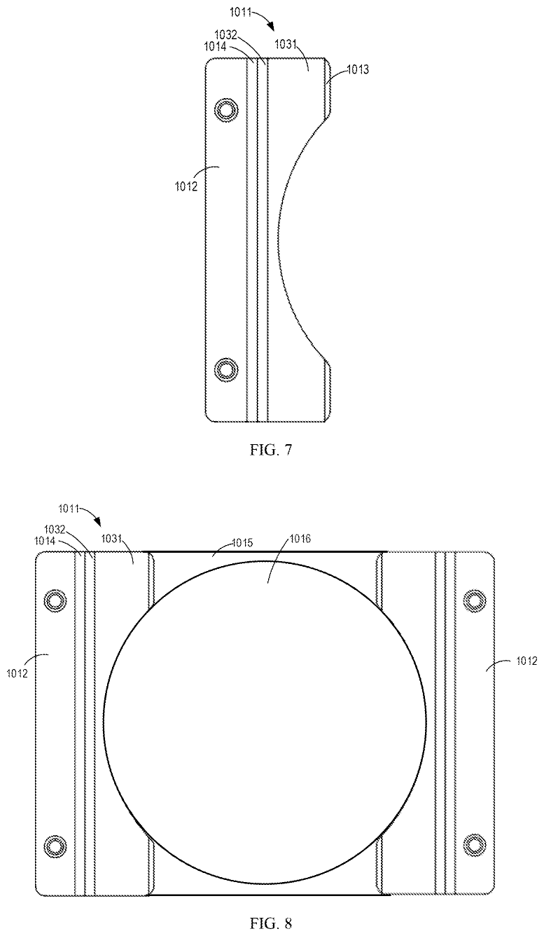

The second bent portion 1013 is bent towards the electrical fan 300 to thereby limit the electrical fan 300 together with the side wall 201. That is, the electrical fan 300 is limited between the second bent portion 1013 and the side wall 201 without blocking airflow provided by the electrical fan 300. For example, as shown in FIGS. 5 and 7, the second bent portion 1013 may be provided with an arc-shaped recess adapt to the airflow path provided by the electrical fan 300. In this way, the second bent portion 1013 will not obstruct the airflow provided by the electrical fan 300.

Besides the first bent portion 1012 and the second bent portion 1013, the half portion 1011 further comprises an intermediate portion 1014 which is arranged between the first bent portion 1012 and the second bent portion 1013. The intermediate portions 1014 of the pair of half portions 1011 can provide limitation for the electrical fan 300 in an extension direction of the side wall 201.

The limiting member 101 comprising a pair of half portions 1011 can improve the flexibility of replacing the electrical fans 300 with different sizes for the cabinet 200. For example, when the electrical fan 200 needs to be replaced with a new electrical fan having a larger width, it is only necessary to adjust a position of one of the half portions 1011 to make the distance between the half portions 1011 consistent with the width of the new electrical fan 300, without replacing the limiting member 101. In this way, the limiting member 101 with half portions 1011 can adapt to a variety of electrical fans with different sizes, to thereby improve the applicability of the mounting assembly 100.

It is to be understood that the above embodiments where the limiting member 101 comprises a pair of half portions 1011 are merely illustrative, without suggesting any limitation as to the scope of the present disclosure. Any other suitable structure or arrangement is also possible. For example in some alternative embodiments, the limiting member 101 may also be integrally formed.

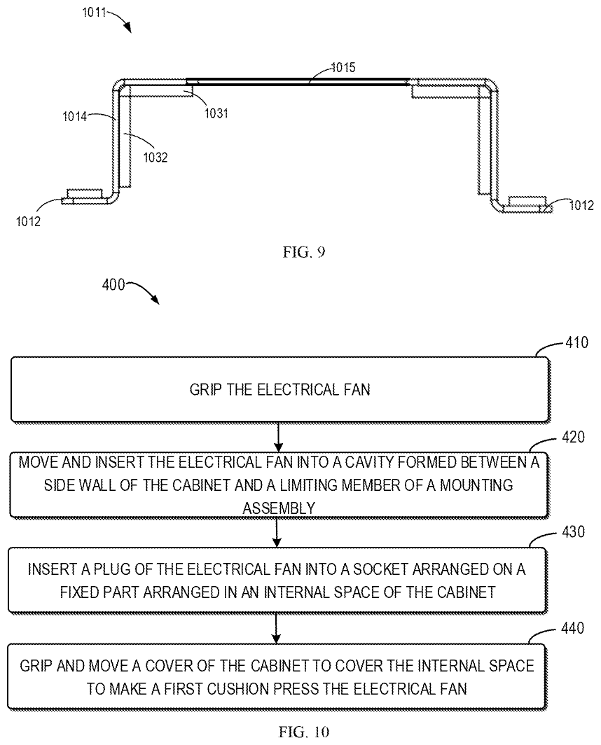

Specifically, as shown in FIGS. 8 and 9, in some embodiments, the limiting member 101 is integrally formed and comprises a pair of first bent portions 1012, a limiting portion 1015 and a pair of intermediate portions 1014 arranged between the pair of first bent portions 1012 and the limiting portion 1015. Similar to the limiting member 101 with two separated half portions 1011, the first bent portions 1012 of the integrally formed limiting member 101 are bent away from the electrical fan 300 and used to be attached to the side wall 201. In this way, the limiting member 101 can be mounted on the side wall 201 more easily.

The limiting portion 1015 can limit the electrical fan 300 together with the side wall 201. That is, the electrical fan 200 can be limited between the limiting portion 1015 and the side wall 201. To prevent from causing obstacle for airflow provided by the electrical fan 300, the limiting portion 1015 may comprise at least one vent 1016 for the airflow to pass through. In some embodiments, the vent 1016 may have a form of a single circle as shown in FIG. 8. In some alternative embodiments, the vent 1016 may also take the form of multiple small holes each having any appropriate shape, for example, circle, rectangle, triangle, and so on. The limiting member 101 with the integral structure can further facilitate the mounting of the limiting member 101 on the side wall 201.

In some embodiments, the mounting assembly 100 may further comprise cushions to prevent shaking of the electrical fan 300 during operation. As shown in FIGS. 5-9, the cushions may comprise a first cushion 103 arranged between the limiting member 101 and the side wall 201 to provide cushion for the electrical fan 300. With the cushions between the mounting assembly 100 and the electrical fan 300, even if the electrical fan 300 vibrates slightly in the cavity, it will not make noise. In this way, the service life of the electrical fan 300 can be extended while improving the user experience.

In some embodiments, the first cushion 103 may comprise at least two portions, namely, a first portion 1031 arranged between the second bent portion 1013 or the limiting portion 1015 and the electrical fan 300 and/or a second portion 1032 arranged between the intermediate portion 1014 and the electrical fan 300. In some embodiments, the first portion 1031 and the second portion 1032 of the first cushion 103 may be separated portions. In some alternative embodiments, the first portion 1031 and the second portion 1032 may also be integral. For example, by bending an integral cushion, the first portion 1031 and the second portion 1032 to be respectively attached to the second bent portion 1013 or the limiting portion 1015 and the intermediate portion 1014 can be formed. Additionally or alternatively, in some embodiments, the first cushion 103 may further comprise a third portion arranged between the side wall 201 and the electrical fan 300.

In some embodiments, the first cushion 103 may further comprise a fourth portion 1033 arranged between a bottom wall 203 of the cabinet 200 and the electrical fan 300. On the one hand, the fourth portion 1033 can provide a certain buffer space for the electrical fan 300 when it is pressed by the stopping member 102. On the other hand, with the above four portion, the first cushion 103 can provide cushion for the electrical fan 300 in various directions, and thus the noise cause by vibration of the electrical fan 300 during operation can be significantly reduced, thereby improving the user experience.

In some embodiments, the cushions may further comprise a second cushion 104 arranged between the stopping member 102 and the electrical. Similar to the fourth portion 1033 of the first cushion 103, the second cushion 104 not only can provide a certain buffer space for the electrical fan 300, but also can efficiently prevent the electrical fan 300 from vibrating in the cavity.

In some embodiments, one of the second cushion 104 and the stopping member 102 can be omitted. For example, in some embodiments, the stopping member 102 itself may comprise a deformable portion such as a spring or a cushion. When the stopping member 102 presses the electrical fan 300 in the insertion direction D, the deformable portion can be deformed. In this way, the vibration of the electrical fan 300 during operation can be compensated by the deformable part, and thus, the second cushion 104 is no longer needed. In some alternative embodiments, the second cushion 104 itself may be used as the stopping member 102. That is, in some embodiments, the second cushion 104 may also be arranged at the corresponding position of the cover 202 to function as the stopping member 102. This arrangement improves the flexibility of using the mounting assembly 100.

To facilitate the electrical connections for the electrical fan 300, in some embodiments, the cabinet 200 according to embodiments of the present disclosure may comprise a fixed part 204 arranged in the internal space. The fixed part 204 may be used for a socket 205 to be arranged thereon. The socket 205 is used to receive a plug 301 of the electrical fan 300. In this way, the plug 301 can be inserted into the socket 205 by automated means such as robots, etc., to thereby further facilitate the automatic mounting of the electrical fan 300.

According to other aspects of the present disclosure, a method 400 of mounting an electrical fan 300 in a cabinet 200 with an automated mean such as a robot is provided. FIG. 10 shows a flowchart illustrating a method 400 of mounting an electrical fan 300 in a cabinet 200 with an automated mean. As shown in FIG. 10, in block 410, the electrical fan 300 may be gripped, for example, by an end actuator of a robot. In block 420, the electrical fan 300 is then moved and inserted into the cavity formed by the limiting member 101 and a side wall 201 of the cabinet 200.

In block 430, the plug 301 of the electrical fan 300 can then be inserted into the socket 205 arranged on the fixed part 204, for example, by the actuator of the robot. In block 440, the cover 202 is gripped and moved to cover the internal space to thereby make the stopping member 102 press the electrical fan 300 in the insertion direction D. In this way, the electrical fan 300 can be mounted in the cabinet 200 with automated means, to thereby improve the assembly efficiency.

It should be appreciated that the above detailed embodiments of the present disclosure are only for exemplifying or explaining principles of the present disclosure and do not limit the present disclosure. Therefore, any modifications, equivalent alternatives and improvements, etc. without departing from the spirit and scope of the present disclosure shall be comprised in the scope of protection of the present disclosure. Meanwhile, appended claims of the present disclosure aim to cover all the variations and modifications falling under the scope and boundary of the claims or equivalents of the scope and boundary.

1. A mounting assembly for an electrical fan, comprising:
a limiting member arranged on a side wall of a cabinet, wherein the limiting member is configured so that a cavity is formed between the side wall and the limiting member, wherein the cavity is configured for receiving the electrical fan, the limiting member is configured to define an opening through which the electrical fan is inserted into the cavity along an insertion direction; and
a stopping member arranged on a cover of the cabinet and adapted to press the electrical fan in the insertion direction when the cover is mounted on the side wall.

2. The mounting assembly of claim 1, further comprising:
a first cushion arranged between the limiting member and the side wall to provide cushion for the electrical fan.

3. The mounting assembly of claim 1, further comprising:
a second cushion arranged between the stopping member and the electrical fan.

4. The mounting assembly of claim 2, wherein the limiting member comprises:
a pair of half portions arranged at opposite sides of the electrical fan, each of the half portions comprising:
a first bent portion bent away from the electrical fan and adapted to be attached on the side wall; and
a second bent portion bent towards the electrical fan and adapted to limit the electrical fan together with the side wall without blocking airflow provided by the electrical fan.

5. The mounting assembly of claim 4, wherein the half portion further comprises:
an intermediate portion arranged between the first and second bent portions and adapted to limit the electrical fan between the intermediate portions.

6. The mounting assembly of claim 5, wherein the first cushion comprises at least one of:
a first portion arranged between the second bent portion and the electrical fan;
a second portion arranged between the intermediate portion and the electrical fan; and
a third portion arranged between the side wall and the electrical fan.

7. The mounting assembly of claim 2, wherein the first cushion further comprises:
a fourth portion arranged on a bottom wall of the cabinet opposite to the cover.

8. The mounting assembly of claim 2, wherein the limiting member is integrally formed and comprises:
a pair of first bent portions bent away from the electrical fan and adapted to be attached on the side wall;
a limiting portion adapted to limit the electrical fan together with the side wall, the limiting portion comprising at least one vents for airflow provided by the electrical fan to pass through; and
a pair of intermediate portions arranged between the limiting portion and the pair of first bent portions and adapted to limit the electrical fan therebetween.

9. A cabinet comprising:
side walls and a bottom wall forming an internal space for receiving electrical devices;
a cover for covering the internal space; and
at least one mounting assembly according to claim 1 for mounting at least one electrical fan on at least one of the side walls.

10. The cabinet of claim 9, further comprising:
at least one fixed part arranged in the internal space and adapted for a socket to be arranged thereon, the socket adapted to receive a plug of the electrical fan to provide electrical connections for the electrical fan.

11. A method of mounting an electrical fan in a cabinet with an automated mean, comprising:
gripping the electrical fan;
moving and inserting the electrical fan into a cavity formed between a side wall of the cabinet and a limiting member of a mounting assembly;
inserting a plug of the electrical fan into a socket arranged on a fixed part arranged in an internal space of the cabinet; and
gripping and moving a cover for the cabinet to cover the internal space to make a first cushion press the electrical fan.

12. The cabinet according to claim 9,
wherein the at least one mounting assembly further comprises:
a second cushion arranged between the stopping member and the electrical fan.

13. The cabinet according to claim 9,
wherein the at least one mounting assembly further comprises:
a first cushion arranged between the limiting member and the side wall to provide cushion for the electrical fan.

14. The cabinet according to claim 13,
wherein the first cushion comprises:
a fourth portion arranged on a bottom wall of the cabinet opposite to the cover.

15. The cabinet according to claim 13,
wherein the limiting member is integrally formed and comprises:
a pair of first bent portions bent away from the electrical fan and adapted to be attached on the side wall;
a limiting portion adapted to limit the electrical fan together with the side wall, the limiting portion comprising at least one vents for airflow provided by the electrical fan to pass through; and
a pair of intermediate portions arranged between the limiting portion and the pair of first bent portions and adapted to limit the electrical fan therebetween.

16. The cabinet according to claim 13,
wherein the limiting member comprises:
a pair of half portions arranged at opposite sides of the electrical fan, each of the half portions comprising:
a first bent portion bent away from the electrical fan and adapted to be attached on the side wall; and
a second bent portion bent towards the electrical fan and adapted to limit the electrical fan together with the side wall without blocking airflow provided by the electrical fan.

17. The cabinet according to claim 16,
wherein the half portion further comprises:
an intermediate portion arranged between the first and second bent portions and adapted to limit the electrical fan between the intermediate portions.

18. The cabinet according to claim 17,
wherein the first cushion comprises:
a first portion arranged between the second bent portion and the electrical fan.

19. The cabinet according to claim 17,
wherein the first cushion comprises:
a second portion arranged between the intermediate portion and the electrical fan.

20. The cabinet according to claim 17,
wherein the first cushion comprises:
a third portion arranged between the side wall and the electrical fan.
